(19) United States
(12) Patent Application Publication
(10) Pub. No.: US 2013/0234224 A1
(43) Pub. Date: Sep. 12, 2013

(54) SEMICONDUCTOR STORAGE DEVICE AND MANUFACTURING METHOD FOR THE SAME

(71) Applicant: Kenji AOYAMA, Yokohama-Shi (JP)

(72) Inventor: Kenji AOYAMA, Yokohama-Shi (JP)

(73) Assignee: Kabushiki Kaisha Toshiba, Tokyo (JP)

(21) Appl. No.: 13/590,586

(22) Filed: Aug. 21, 2012

(30) Foreign Application Priority Data
Mar. 8, 2012 (JP) 2012-051780

(51) Int. Cl. H01L 29/788; H01L 21/283

(52) U.S. Cl. 257/316; 438/591; 257/E29.3; 257/E21.209

(57) ABSTRACT

According to one embodiment, a semiconductor storage device comprises a memory cell transistor including a first insulating film, a first floating gate, a second insulating film, a second floating gate, a third insulating film and a control gate which are sequentially formed on a substrate, and a select transistor including a fourth insulating film, a first electrode layer, a fifth insulating film, a second electrode layer, a sixth insulating film and a third electrode layer which are sequentially formed on the substrate. Openings are provided in at least parts of the fifth insulating film and the sixth insulating film. The first electrode layer, the second electrode layer and the third electrode layer are electrically connected via the openings.

### CROSS REFERENCE TO RELATED APPLICATION

This application is based upon and claims benefit of priority from the Japanese Patent Application No. 2012-51780, filed on Mar. 8, 2012, the entire contents of which are incorporated herein by reference.

### FIELD

Embodiments described herein relate generally to a semiconductor storage device and a manufacturing method for a semiconductor storage device.

### BACKGROUND

Regarding a semiconductor storage device such as a NAND flash memory, there has been proposed a configuration where a floating gate of a memory cell transistor includes a lower floating gate, an upper floating gate, and an inter-gate insulating film provided between the lower floating gate and the upper floating gate. With such a configuration formed, it is possible to make a memory cell density higher while suppressing deterioration in writing characteristics of the memory cell transistor, an adjacent cell interfering effect, an electric charge escape and the like.

A select transistor of a conventional NAND flash memory has a configuration where a groove (opening) is provided in an insulating film between a first electrode layer corresponding to a floating gate and a second electrode layer corresponding to a control gate, to connect between the first electrode layer and the second electrode layer. When the floating gate of the memory cell transistor is configured to have the lower floating gate, the upper floating gate and the inter-gate insulating film provided between the lower floating gate and the upper floating gate as described above, the first electrode layer of the select transistor is similarly configured to have the lower electrode layer, the upper electrode layer and the insulating film provided between the lower electrode layer and the upper electrode layer. In the select transistor with such a configuration, since the lower electrode layer holds an electric charge as does the floating gate, a threshold voltage may change, to bring about an erroneous operation. Further, it has been necessary to apply a voltage for a total of a tunnel insulating film and the insulating film provided between the lower electrode layer and the upper electrode layer, thus increasing power consumption. Hence the higher density of the memory cell has induced deterioration in characteristics of the select transistor.

### BRIEF DESCRIPTION OF THE DRAWINGS

FIG. 1 is a plan view of a semiconductor storage device according to a first embodiment;

FIGS. 2A and 2B are sectional views of the semiconductor storage device according to the first embodiment;

FIGS. 3A and 3B are process sectional views explaining a manufacturing method for the semiconductor storage device according to the first embodiment;

FIGS. 4A and 4B are process sectional views subsequent to FIGS. 3A and 3B;

FIGS. 5A and 5B are process sectional views subsequent to FIGS. 4A and 4B;

FIGS. 6A and 6B are process sectional views subsequent to FIGS. 5A and 5B;

FIGS. 7A and 7B are process sectional views subsequent to FIGS. 6A and 6B;

FIGS. 8A and 8B are process sectional views subsequent to FIGS. 7A and 7B;

FIGS. 9A and 9B are process sectional views explaining a manufacturing method for a semiconductor storage device according to a second embodiment;

FIGS. 10A and 10B are process sectional views subsequent to FIGS. 9A and 9B;

FIGS. 11A and 11B are process sectional views subsequent to FIGS. 10A and 10B;

FIGS. 12A and 12B are process sectional views subsequent to FIGS. 11A and 11B;

FIGS. 13A and 13B are sectional views of the semiconductor storage device according to the second embodiment;

FIGS. 14A and 14B are sectional views of a semiconductor storage device according to a modified example;

FIG. 15 is a sectional view of a semiconductor storage device according to a third embodiment;

FIG. 16 is a sectional view of a semiconductor storage device according to a modified example; and

FIG. 17 is a sectional view of a semiconductor storage device according to a modified example.

### DETAILED DESCRIPTION

According to one embodiment, a semiconductor storage device comprises a memory cell transistor including a first insulating film, a first floating gate, a second insulating film, a second floating gate, a third insulating film and a control gate which are sequentially formed on a substrate, and a select transistor including a fourth insulating film, a first electrode layer, a fifth insulating film, a second electrode layer, a sixth insulating film and a third electrode layer which are sequentially formed on the substrate. Openings are provided in at least parts of the fifth insulating film and the sixth insulating film. The first electrode layer, the second electrode layer and the third electrode layer are electrically connected via the openings.

Embodiments will now be explained with reference to the accompanying drawings.

### FIRST EMBODIMENT

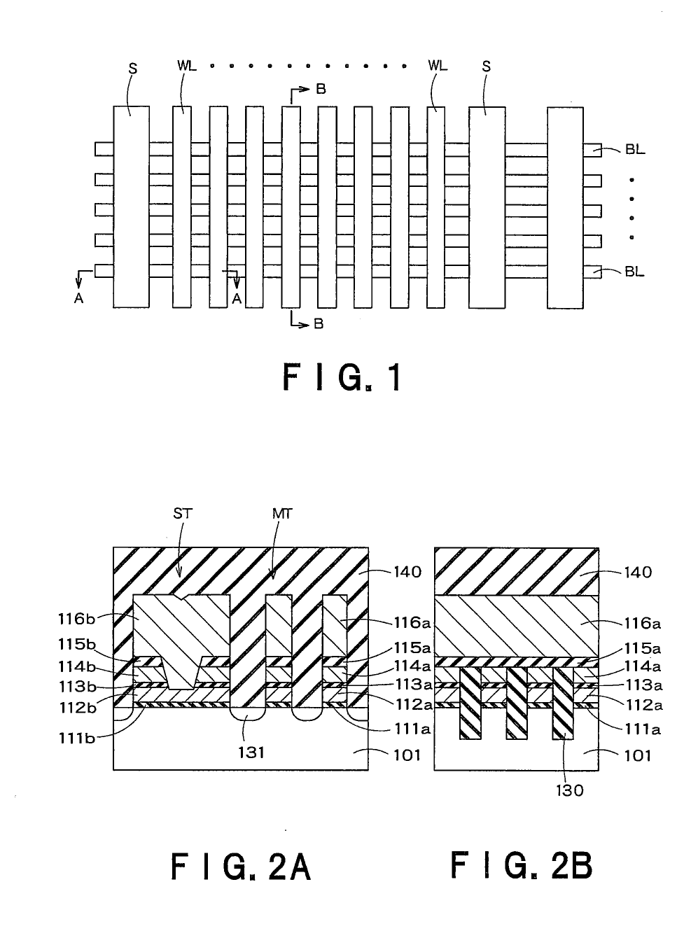

FIG. 1 is a plan view of a semiconductor storage device according to a first embodiment. The semiconductor storage device is an NAND flash memory.

As shown in FIG. 1, the semiconductor storage device is provided with a plurality of bit lines BL extending along a first direction, a plurality of word lines WL and select lines S extending along a second direction orthogonal to the first direction.

A point of intersection between the bit line BL and the word line WL is provided with a memory cell transistor. Further, a point of intersection between the bit line BL and the select line S is provided with a select transistor. The memory cell transistor is electrically connected to the bit line BL and the word line WL. Moreover, the select transistor is electrically connected to the bit line BL and the select line S.

FIG. 2A shows a vertical sectional view along a line A-A of FIG. 1, and FIG. 2B shows part of a vertical sectional view along a line B-B of FIG. 1.

As shown in FIG. 2A, an impurity diffused layer 131 is formed in a surface portion of a semiconductor substrate 101. On the semiconductor substrate 101 between the impurity diffused layers 131, a memory cell transistor MT is formed, which is sequentially laminated with a tunnel insulating film 111a, a lower floating gate 112a, an IFD (Inter Floating-Gate Dielectric) film 113a, an upper floating gate 114a, an IPD (Inter Poly-Si Dielectric) film 115a and a control gate 116a. The memory cell transistor MT has a two-layered structure where the floating gates sandwich the IFD film 113a.

As shown in FIG. 2B, in the memory cell transistor MT, a plurality of embedded element separated regions 130 are formed on the semiconductor substrate 101 along a word-line WL direction at predetermined intervals. On the semiconductor substrate 101 between the element separated regions 130, the tunnel insulating film 111a, the lower floating gate 112a, the IFD film 113a and the upper floating gate 114a are sequentially formed.

The IPD film 115a is formed on the upper floating gate 114a and the element separated region 130. The control gate 116a is formed on this IPD film 115a.

As shown in FIGS. 1 and 2A, a select transistor ST is formed at each end of the plurality of memory cell transistors MT arrayed in a bit-line BL direction. The select transistor ST includes a tunnel insulating film 111b, a first electrode layer 112b, a first inter-electrode insulating film 113b, a second electrode layer 114b, a second inter-electrode insulating film 115b and a third electrode layer 116b, which are sequentially formed on the semiconductor substrate 101. The select transistor ST has a similar configuration to the memory cell transistor MT, and the tunnel insulating film 111b, the first electrode layer 112b, the first inter-electrode insulating film 113b, the second electrode layer 114b, the second inter-electrode insulating film 115b and the third electrode layer 116b in the select transistor ST respectively correspond to the tunnel insulating film 111a, the lower floating gate 112a, the IFD film 113a, the upper floating gate 114a, the IPD film 115a and the control gate 116a in the memory cell transistor MT.

However, in the select transistor ST, openings are formed in part of the first inter-electrode insulating film 113b and part of the second inter-electrode insulating film 115b, to connect among the first electrode layer 112b, the second electrode layer 114b and the third electrode layer 116b.

When the opening is not provided in the first inter-electrode insulating film 113b, the first electrode layer 112b holds an electric charge as does the floating gate, which may cause a change in threshold voltage of the select transistor ST, to bring about an erroneous operation. Further, when the opening is not provided in the first inter-electrode insulating film 113b, driving the select transistor ST necessitates application of a voltage corresponding to a total of the tunnel insulating film 111b and the first inter-electrode insulating film 113b, thus increasing power consumption.

As opposed to this, in the present embodiment, the opening is formed in part of the first inter-electrode insulating film 113b, to connect among the first electrode layer 112b, the second electrode layer 114b and the third electrode layer 116b, and hence the first electrode layer 112b does not hold an electric charge as does the floating gate, allowing prevention of a threshold voltage of the select transistor ST from changing and an erroneous operation from occurring. Further, a voltage corresponding to the tunnel insulating film 111b may be applied for driving the select transistor ST, thus allowing suppression of power consumption. A size of the opening of the first inter-electrode insulating film 113b is not particularly restricted, and the opening may have the same size as the first inter-electrode insulating film 113b, namely, the first inter-electrode insulating film 113b may be omitted.

Further, in the present embodiment, the floating gate of the memory cell transistor MT is made up of the lower floating gate 112a and the upper floating gate 114a, and the IFD film 113a is provided between the lower floating gate 112a and the upper floating gate 114a. Thereby, a coupling ratio between the upper floating gate 114a and the control gate 116a is improved, to increase an electric field to be applied to the tunnel insulating film 111a, thus leading to improvement in writing characteristics of the memory cell transistor MT. Further, a capacity within a cell increases and the coupling ratio thus become higher, thereby to suppress the adjacent cell interfering effect.

Moreover, the tunnel insulating film 111a and the IFD film 113a become FN (Fowler-Nordheim) films, thereby to suppress an escape of an electric charge within the lower floating gate 112a to the substrate 101 and also suppress an escape of an electric charge within the upper floating gate 114a to the lower floating gate 112a. This allows the memory cell transistor MT to keep holding an electric charge for a long period of time. The memory cell transistor MT can be higher in density while suppressing deterioration in writing characteristics, the adjacent cell interfering effect, the electric charge escape and the like.

As thus described, according to the present embodiment, it is possible to make the density of the memory cell transistor MT higher, while suppressing deterioration in characteristics of the select transistor ST.

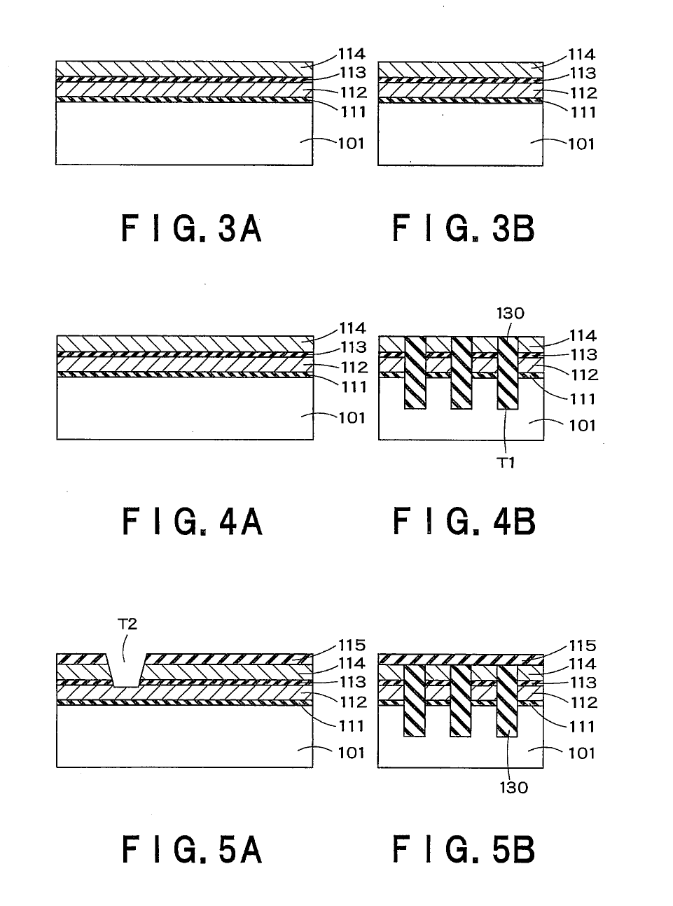

Next, a manufacturing method for such a semiconductor storage device will be described using process sectional views shown in FIGS. 3A and 3B to FIGS. 8A and 8B. A and B in each figure respectively show cross sections corresponding to FIGS. 2A and 2B.

First, as shown in FIGS. 3A and 3B, an insulating film 111 to be materials for the tunnel insulating films 111a, 111b, an electrode layer 112 to be materials for the lower floating gate 112a and the first electrode layer 112b, an insulating film 113 to be materials for the IFD film 113a and the first inter-electrode insulating film 113b, and an electrode layer 114 to be materials for the upper floating gate 114a and the second electrode layer 114b are sequentially formed on the substrate 101.

The insulating film 111 is, for example, a silicon oxide film, a silicon oxy-nitride film or a silicon nitride film. The electrode layers 112, 114 are, for example, made up of polysilicon, polysilicon doped with boracic acid or phosphorus, metal such as TiN, TaN or W, or silicide thereof. The insulating film 113 is, for example, a silicon oxide film, a silicon oxy-nitride film, a silicon nitride film, a Al₂O₃ film, a HfOₓ film, a TaOₓ film, or a La₂Oₓ film.

Subsequently, as shown in FIGS. 4A and 4B, a mask layer (not shown) is formed on the electrode layer 114, and by lithography and etching, this mask layer is patterned in the form of a plurality of bands along the bit-line BL direction. The mask layer is, for example, a silicon oxide film. Then, using the patterned mask layer, the electrode layer 114, the insulating film 113, the electrode layer 112, the insulating film 111 and the substrate 101 are etched, to form a plurality of grooves T1. The mask layer is removed and an insulating film such as a silicon oxide film is embedded in the groove T1, which is then smoothed by CMP (Chemical-Mechanical Polishing), to form the element separated region 130.

Next, as shown in FIGS. 5A and 5B, an insulating film 115 to be materials for the IPD film 115a and the second inter-electrode insulating film 115b is formed on the electrode layer 114 and the element separated region 130. The insulating film 115 is, for example, a silicon oxide film, a silicon oxy-nitride film, a silicon nitride film, a Al₂O₃ film, a HfOₓ film, a TaOₓ film, or La₂Oₓ film.

Then, in the region where the select transistor ST is provided, the insulating film 115, the electrode layer 114 and the insulating film 113 are removed by lithography and etching (e.g. RIE), to form a groove T2. At this time, part of the electrode layer 112 may be removed. The groove T2 corresponds to the opening that is provided in the first inter-electrode insulating film 113b and the second inter-electrode insulating film 115b of the select transistor ST. Further, since an amount of removal is smaller in a deeper place in typical anisotropic etching, a width of the groove T2 gets narrower toward a lower place. Hence the opening provided in the first inter-electrode insulating film 113b has a smaller width than that of the opening provided in the second inter-electrode insulating film 115b.

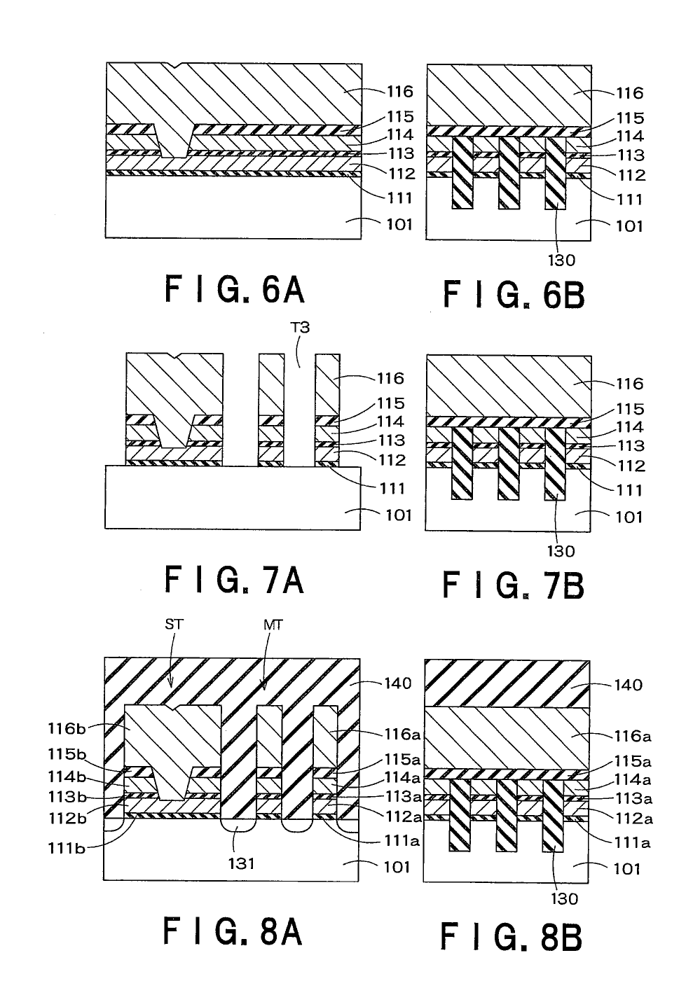

Next, as shown in FIGS. 6A and 6B, an electrode layer 116 to be materials for the control gate 116a and the third electrode layer 116b is formed on the insulating film 115. The groove T2 is embedded with the electrode layer 116. The electrode layer 116 is made up of polysilicon, polysilicon doped with boracic acid or phosphorus, metal such as TiN, TaN, W, Ni or Co, or silicide thereof.

Next, as shown in FIGS. 7A and 7B, a mask layer (not shown) is formed on the electrode layer 116, and by lithography and etching, this mask layer is patterned in the form of a plurality of bands along the word-line WL direction. Then, using the patterned mask layer, the electrode layer 116, the insulating film 115, the electrode layer 114, the insulating film 113, the electrode layer 112 and the insulating film 111 are etched, to form a plurality of grooves T3.

Next, as shown in FIGS. 8A and 8B, the impurity diffused layer 131 is formed on the substrate 101. An inter-layer insulating film 140 is then formed on the substrate 101 such that the inter-layer insulating film 140 is embedded in the groove T3. Thereafter, a contact plug, a via plug, a wiring layer and the like are formed.

This leads to formation of the memory cell transistor MT laminated with the tunnel insulating film 111a, the lower floating gate 112a, the IFD film 113a, the upper floating gate 114a, the IPD film 115a and the control gate 116a.

Further, the tunnel insulating film 111b, the first electrode layer 112b, the first inter-electrode insulating film 113b, the second electrode layer 114b, the second inter-electrode insulating film 115b and the third electrode layer 116b are laminated, to form the select transistor ST connected with the first electrode layer 112b, the second electrode layer 114b and the third electrode layer 116b via the openings provided in the first inter-electrode insulating film 113b and the second inter-electrode insulating film 115b. In the select transistor ST, the third electrode layer 116b is in contact with the first electrode layer 112b and the second electrode layer 114b.

As described above, in the present embodiment, the opening is formed in part of the first inter-electrode insulating film 113b and part of the second inter-electrode insulating film 115b, to connect among the first electrode layer 112b, the second electrode layer 114b and the third electrode layer 116b, and hence the first electrode layer 112b does not hold an electric charge as does the floating gate, allowing prevention of a threshold voltage of the select transistor ST from changing and an erroneous operation from occurring. Further, a voltage corresponding to the tunnel insulating film 111b may be applied for driving the select transistor ST, thus allowing suppression of power consumption.

Moreover, with the floating gate of the memory cell transistor MT made up of the lower floating gate 112a, the IFD film 113a and the upper floating gate 114a, the memory cell transistor MT can be higher in density while suppressing deterioration in writing characteristics, the adjacent cell interfering effect, the electric charge escape and the like.

As thus described, according to the present embodiment, it is possible to make the density of the memory cell transistor MT higher, while suppressing deterioration in characteristics of the select transistor ST.

### SECOND EMBODIMENT

In the above first embodiment, in the process shown in FIG. 5A, the groove T2 is formed, thereby to form the openings provided in the above first inter-electrode insulating film 113b and the second inter-electrode insulating film 115b of the select transistor ST. That is, the openings provided in the first inter-electrode insulating film 113b and the second inter-electrode insulating film 115b are formed in the same process in the above first embodiment, but these may be formed in separate processes.

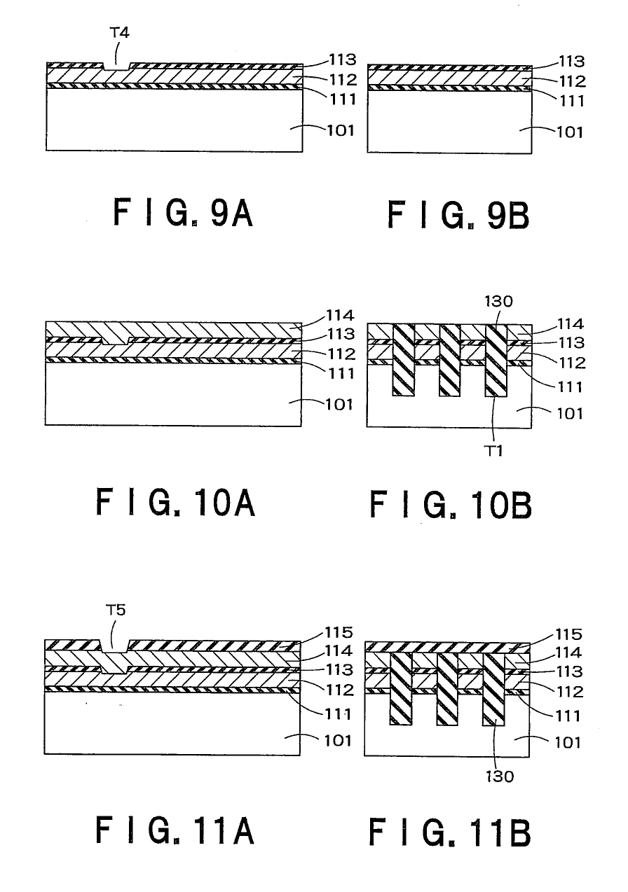

A manufacturing method for the semiconductor storage device in the case of forming the opening provided in the first inter-electrode insulating film 113b and the opening provided in the second inter-electrode insulating film 115b in separate processes will be described using process sectional views shown in FIGS. 9A and 9B to 12A to 12B. A and B in each figure respectively show cross sections corresponding to FIGS. 2A and 2B.

First, as shown in FIGS. 9A and 9B, the insulating film 111 to be materials for the tunnel insulating films 111a, 111b, the electrode layer 112 to be materials for the lower floating gate 112a and the first electrode layer 112b, and the insulating film 113 to be materials for the IFD film 113a and the first inter-electrode insulating film 113b are sequentially formed on the substrate 101.

Then, in the region where the select transistor ST is provided, the insulating film 113 is removed by lithography and etching, to form a groove T4. The groove T4 corresponds to the opening that is provided in the first inter-electrode insulating film 113b of the select transistor ST.

Next, as shown in FIGS. 10A and 10B, the electrode layer 114 to be materials for the upper floating gate 114a and the second electrode layer 114b is formed on the insulating film 113. The groove T4 is embedded with the electrode layer 114.

Subsequently, a mask layer (not shown) is formed on the electrode layer 114, and by lithography and etching, this mask layer is patterned in the form of a plurality of bands along the bit-line BL direction. Then, using the patterned mask layer, the electrode layer 114, the insulating film 113, the electrode layer 112, the insulating film 111 and the substrate 101 are etched, to form a plurality of grooves T1. The mask layer is removed and an insulating film such as a silicon oxide film is embedded in the groove T1, which is then smoothed by CMP (Chemical-Mechanical Polishing), to form the element separated region 130.

Next, as shown in FIGS. 11A and 11B, the insulating film 115 to be materials for the IPD film 115a and the second inter-electrode insulating film 115b is formed on the electrode layer 114 and the element separated region 130. Then, in the region where the select transistor ST is provided, the insulating film 115 is removed by lithography and etching (e.g. RIE), to form a groove T5. The groove T5 corresponds to the opening that is provided in the second inter-electrode insulating film 115b of the select transistor ST.

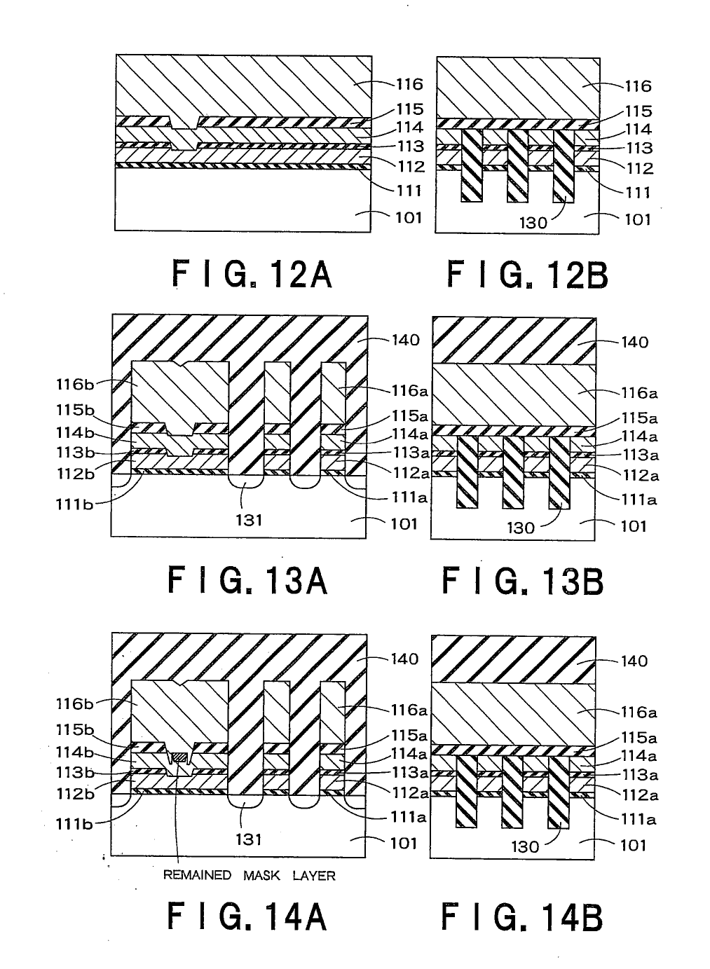

Next, as shown in FIGS. 12A and 12B, the electrode layer 116 to be materials for the control gate 116a and a third electrode layer 116b is formed on the insulating film 115. The groove T5 is embedded wiht the electrode layer 116.

Since subsequent steps are similar to those of the above first embodiment (cf. FIGS. 7A, 7B, 8A, and 8B), descriptions thereof will be omitted. In such a manner, the semiconductor storage device as shown in FIG. 13 is formed. In the select transistor ST shown in FIG. 13, the third electrode layer 116b is in contact with the second electrode layer 114b, and the second electrode layer 114b is in contact with the first electrode layer 112b.

In the above first embodiment, in the process shown in FIG. 5A, the insulating film 115, the electrode layer 114 and the insulating film 113 are removed, to form the groove T2. When film thicknesses of the insulating film 115, the electrode layer 114, the insulating film 113 and the electrode layer 112 are respectively referred to as d5, d4, d3 and d2, an etching film thickness is d5+d4+d3, and an etching depth variation allowance is d2 in the process shown in FIG. 5A.

On the other hand, in the present embodiment, in the process of forming the groove T4 shown in FIG. 9A, an etching film thickness is d3, and an etching depth variation allowance is d2 in the process shown in FIG. 9A. Further, in the process of forming the groove T5 shown in FIG. 11A, an etching film thickness is d5, and an etching depth variation allowance is d4+d3+d2. According to the present embodiment, the etching depth variation allowance with respect to the etching film thickness can be taken large as compared with the above first embodiment, and the opening provided in the first inter-electrode insulating film 113b and the opening provided in the second inter-electrode insulating film 115b can be stably formed.

In the above second embodiment, the groove T5 may not be formed immediately above the groove T4. This is because, even when a position (plane position) of the opening provided in the first inter-electrode insulating film 113b and a position (plane position) of the opening provided in the second inter-electrode insulating film 115b are displaced, the first electrode layer 112b, the second electrode layer 114b and the third electrode layer 116b are connected.

In the above first embodiment, the width of the opening provided in the first inter-electrode insulating film 113b is smaller than the width of the opening provided in the second inter-electrode insulating film 115b. However, in the second embodiment, since these openings are formed in the separate processes, the width of the opening provided in the first inter-electrode insulating film 113b can be made equal to or larger than the width of the opening provided in the second inter-electrode insulating film 115b.

Although the mask layer is formed on the electrode layer 114 in formation of the groove T1 in the process shown in FIGS. 10A and 10B in the above second embodiment, part of the mask layer may remain in an upper portion of the groove T4 (opening of the first inter-electrode insulating film 113b) even after removal of the mask layer, as shown in FIG. 14. Even when part of the mask layer remains as thus described, the first electrode layer 112b, the second electrode layer 114b and the third electrode layer 116b are connected.

### THIRD EMBODIMENT

In the above first and second embodiments, the IPD film 115 and the lower surface of the control gate 116 are flat. In other words, the upper surface of the upper floating gate 114 and the upper surface of the element separated region 130 have the same height.

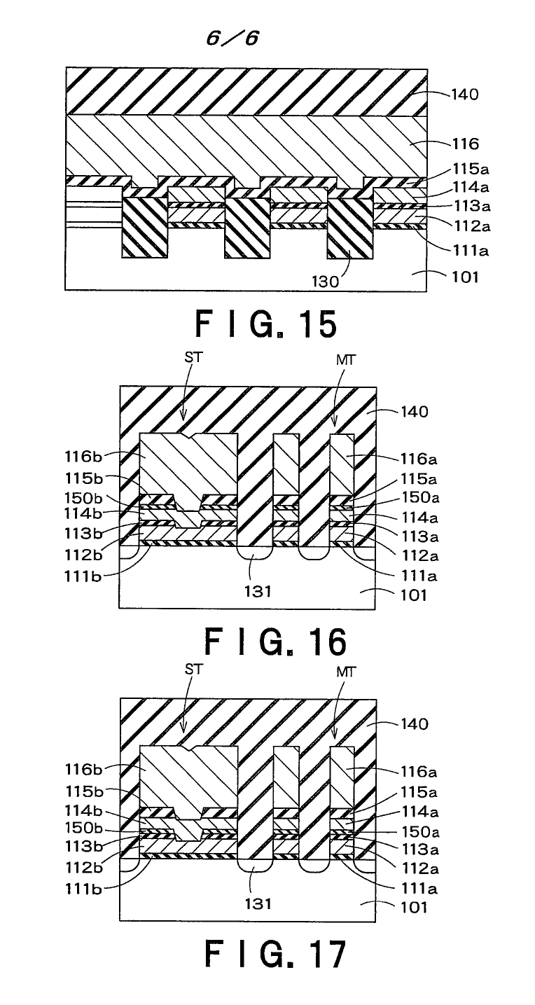

As opposed to this, in the present embodiment, as shown in FIG. 15, the upper surface of the element separated region 130 is made to have a smaller height than the upper surface of the upper floating gate 114a, and the IPD film 115a and the lower surface of the control gate 116a are formed in an uneven shape in accordance with shapes of the surfaces of the element separated region 130 and the upper floating gate 114a.

Specifically, in the processes shown in FIGS. 4B and 10B, the insulating film such as a silicon oxide film is embedded in the groove T1, which is then smoothed by CMP, to remove part of the insulating film embedded in the groove T1 by RIE or the like.

Forming the configuration as shown in FIG. 15, opposed areas of the control gate 116a and the upper floating gate 114a can be increased, thereby to increase a coupling capacitance and a coupling coefficient.

In the above first to third embodiments, as shown in FIG. 16, a charge trap film 150a may be provided on the upper floating gate 114a of the memory cell transistor MT. The charge trap film 150a is, for example, a silicon nitride film or a HfOx film. The charge trap film 150a may be formed immediately below the IPD film 115a as shown in FIG. 16, or may be formed immediately above the IFD film 113a as shown in FIG. 17. In the case of manufacturing the configuration shown in FIG. 17 using the manufacturing method according to the above second embodiment, the groove T4 corresponding to the opening of the IFD film 113a may be formed after formation of the charge trap film 150a on the IFD film 113a.

It is to be noted that in the case of providing the charge trap film 150a on the upper floating gate 114a, a film 150b made of the same material as the charge trap film 150a is formed in the select transistor ST.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A semiconductor storage device, comprising:
a memory cell transistor including a first insulating film, a first floating gate, a second insulating film, a second floating gate, a third insulating film and a control gate which are sequentially formed on a substrate; and
a select transistor including a fourth insulating film, a first electrode layer, a fifth insulating film, a second electrode layer, a sixth insulating film and a third electrode layer which are sequentially formed on the substrate,
wherein openings are provided in at least parts of the fifth insulating film and the sixth insulating film, and the first electrode layer, the second electrode layer and the third electrode layer are electrically connected via the openings.

2. The semiconductor storage device according to claim 1, wherein the opening provided in the fifth insulating film is smaller than the opening provided in the sixth insulating film, and
the third electrode layer is in contact with the first electrode layer and the second electrode layer.

3. The semiconductor storage device according to claim 2, wherein the opening provided in the sixth insulating film is provided above the opening provided in the fifth insulating film.

4. The semiconductor storage device according to claim 1, wherein the opening provided in the fifth insulating film has a larger size than the opening provided in the sixth insulating film, and
the first electrode layer is in contact with the second electrode layer, and the second electrode layer is in contact with the third electrode layer.

5. The semiconductor storage device according to claim 4, wherein a plane position of the opening provided in the fifth insulating film is displaced from a plane position of the opening provided in the sixth insulating film.

6. The semiconductor storage device according to claim 1, wherein a plurality of bit lines extending in a first direction and a plurality of word lines extending in a second direction orthogonal to the first direction are provided, and
the memory cell transistor is provided in an intersecting portion between the bit line and the word line.

7. The semiconductor storage device according to claim 1, wherein the memory cell transistor is further provided with a charge trap film between the second insulating film and the second floating gate.

8. The semiconductor storage device according to claim 7, wherein the select transistor is further provided with a film made of the same material as the charge trap film between the fifth insulating film and the second electrode layer.

9. The semiconductor storage device according to claim 1, wherein the memory cell transistor is further provided with a charge trap film between the second floating gate and the third insulating film.

10. The semiconductor storage device according to claim 9, wherein the select transistor is further provided with a film made of the same material as the charge trap film between the second electrode layer and the sixth insulating film.

11. A manufacturing method for a semiconductor storage device, comprising:
sequentially forming a first insulating film, a first electrode layer, a second insulating film and a second electrode layer on a substrate;
etching the second electrode layer, the second insulating film, the first electrode layer, the first insulating film and the substrate by use of a plurality of band-like mask layers along a first direction, to form a plurality of first grooves;
embedding an insulating film in the first groove, to form an element separated region;
forming a third insulating film on the second electrode layer and the element separated region;
etching the third insulating film, the second electrode layer and the second insulating film in a predetermined region, to form a second groove;
forming a third electrode layer on the third insulating film such that the third electrode layer is embedded in the second groove;
etching the third electrode layer, the third insulating film, the second electrode layer, the second insulating film, the first electrode layer and the first insulating film by use of a plurality of band-like mask layers along a second direction orthogonal to the first direction, to form a plurality of third grooves; and
embedding an inter-layer insulating film in the third groove.

12. The method for manufacturing a semiconductor device according to claim 11, wherein a charge trap film is formed on the second electrode layer before formation of the first groove.

13. The method for manufacturing a semiconductor device according to claim 11, wherein a charge trap film is formed between the second insulating film and the second electrode layer.

14. The method for manufacturing a semiconductor device according to claim 11, wherein a position of the upper surface of the element separated region is lower than a position of the upper surface of the second electrode layer.

15. A manufacturing method for a semiconductor storage device, comprising:
sequentially forming a first insulating film, a first electrode layer and a second insulating film on a substrate;
etching the second electrode layer in a predetermined region, to form a first groove;
forming a second electrode layer on the second insulating film such that the first groove is embedded therein; etching the second electrode layer, the second insulating film, the first electrode layer, the first insulating film and the substrate by use of a plurality of band-like mask layers along a first direction, to form a plurality of second grooves; and
embedding an insulating film in the second grooves, to form an element separated region;
forming a third insulating film on the second electrode layer and the element separated region;
etching the third insulating film in a predetermined region, to form a third groove;
forming the third electrode layer on the third insulating film such that the third groove is embedded therein;
etching the third electrode layer, the third insulating film, the second electrode layer, the second insulating film, the first electrode layer and the first insulating film by use of a plurality of band-like mask layers along a second direction orthogonal to the first direction, to form a plurality of fourth grooves; and
embedding an inter-layer insulating film in the fourth groove.

16. The method for manufacturing a semiconductor device according to claim 15, wherein the third groove is formed in a region above the first groove.

17. The method for manufacturing a semiconductor device according to claim 15, wherein a plane position where the third groove is formed is displaced from a plane position where the first groove is formed.

18. The method for manufacturing a semiconductor device according to claim 15, wherein a charge trap film is formed on the second electrode layer before formation of the second groove.

19. The method for manufacturing a semiconductor device according to claim 15, wherein a charge trap film is formed on the second electrode layer before formation of the first groove.

20. The method for manufacturing a semiconductor device according to claim 15, wherein a position of the upper surface of the element separated region is lower than a position of the upper surface of the second electrode layer.
